(19) United States
(12) Patent Application Publication
(10) Pub. No.: US 2016/0373234 A1
(43) Pub. Date: Dec. 22, 2016

(54) IN-BAND FULL DUPLEX TRANSCEIVER

(71) Applicant: Electronics and Telecommunications Research Institute, Daejeon (KR)

(72) Inventors: Hyung Sik JU, Daejeon (KR); Kapseok CHANG, Daejeon (KR)

(21) Appl. No.: 15/189,277

(22) Filed: Jun. 22, 2016

(30) Foreign Application Priority Data
Jun. 22, 2015 (KR) 10-2015-0088687
Jun. 20, 2016 (KR) 10-2016-0076354

(51) Int. Cl. H04L 5/14; H04B 7/04; H03F 3/24; H04B 15/00

(52) U.S. Cl. CPC H04L 5/14; H04B 15/00; H04B 7/0469; H03F 3/245; H03F 2200/294; H03F 2200/333; H03F 2200/171

(57) ABSTRACT

Disclosed herein is an in-band full duplex transceiver, including: a multi polarized antenna including a plurality of polarized transmitting/receiving units transmitting/receiving different polarizations; and a plurality of transmitting/receiving modules each connected with the plurality of polarized transmitting/receiving units, receiving received signals through the plurality of polarized transmitting/receiving units, and transmitting transmitted signals through the plurality of polarized transmitting/receiving units, in which each of the transmitting/receiving modules may include: an analog circuit unit including a finite impulse response filter that converts an analog received signal received through the corresponding polarized transmitting/receiving unit into a digital received signal, converts a digital transmitted signal into an analog transmitted signal, and uses the analog transmitted signal to cancel self-interference from the analog received signal; and a distributor transmitting the analog received signal input from the corresponding polarized transmitting/receiving unit to the analog circuit unit and transmitting the analog transmitted signal input from the analog circuit unit to the corresponding polarized transmitting/receiving unit.

### CROSS-REFERENCE TO RELATED APPLICATION

This application claims priority to and the benefit of Korean Patent Application Nos. 10-2015-0088687 and 10-2016-0076354 filed in the Korean Intellectual Property Office on Jun. 22, 2015, and Jun. 20, 2016, the entire contents of which are incorporated herein by reference.

### BACKGROUND OF THE INVENTION

(a) Field of the Invention

The present invention relates to an in-band full duplex transceiver, and more particularly, to a multiple-input multiple-output in-band full duplex transceiver.

(b) Description of the Related Art

A half duplex (HD) scheme which is currently in use in a wireless communication system distributes time/frequency to perform transmission or reception. Therefore, the wireless communication system using the HD scheme may maintain orthogonality between transmission and reception. On the other hand, the wireless communication system using the HD scheme has a drawback in that time/frequency resources are consumed.

An in-band full duplex (IFD) scheme is a solution for solving inefficiency of the HD scheme and is a technology of simultaneously performing transmission/reception in an in-band. Theoretically, the IFD scheme may have link capacity up to twice as high as the HD scheme.

Meanwhile, the IFD scheme has a problem in that a self-transmitting signal flows in a receiver, and therefore a much stronger self-interference (SI) signal than an effectively received signal is generated. Accordingly, for the IFD scheme to perform smooth communication, there is a need to cancel the SI.

In the case of sufficiently canceling the SI, an IFD transceiver may have spectral efficiency up to twice as high as an HD transceiver. However, when the SI cancellation (SIC) is implemented in the IFD transceiver, there is a problem in that complexity of the IFD transceiver may be increased. In particular, when the IFD transmitting/receiving technology is applied to a multiple-input multiple-output (MIMO) system, complexity for implementing the SIC may be very greatly increased.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide an in-band full duplex transceiver having an advantage of reducing hardware complexity due to multiple-input multiple-output while effectively canceling self-interference.

An exemplary embodiment of the present invention provides an in-band full duplex transceiver, including: a multi polarized antenna including a plurality of polarized transmitting/receiving units transmitting/receiving different polarizations; and a plurality of transmitting/receiving modules each connected with the plurality of polarized transmitting/receiving units, receiving received signals through the plurality of polarized transmitting/receiving units, and transmitting transmitted signals through the plurality of polarized transmitting/receiving units, in which each of the transmitting/receiving modules may include: an analog circuit unit including a finite impulse response filter that converts an analog received signal received through the corresponding polarized transmitting/receiving unit into a digital received signal, converts a digital transmitted signal into an analog transmitted signal, and uses the analog transmitted signal to cancel self-interference from the analog received signal; and a distributor transmitting the analog received signal input from the corresponding polarized transmitting/receiving unit to the analog circuit unit and transmitting the analog transmitted signal input from the analog circuit unit to the corresponding polarized transmitting/receiving unit.

Another exemplary embodiment of the present invention provides an in-band full duplex transceiver, including: a plurality of multi polarized antennas including a plurality of polarized transmitting/receiving units transmitting/receiving a plurality of polarizations; a plurality of transmitting/receiving modules each connected with the plurality of polarized transmitting/receiving units, receiving received signals through the plurality of polarized transmitting/receiving units, and transmitting transmitted signals through the plurality of polarized transmitting/receiving units; and a plurality of first finite impulse response filters using the transmitted signals to cancel interference between the polarized transmitting/receiving units transmitting/receiving the same polarization as each other from the plurality of multi polarized antennas.

According to an embodiment of the present invention, it is possible to reduce the hardware complexity due to the multiple-input multiple-output of the in-band full duplex transceiver while effectively canceling the self-interference.

### BRIEF DESCRIPTION OF THE DRAWINGS

FIG. 1 is a diagram schematically illustrating an IFD transceiver according to a first exemplary embodiment of the present invention.

FIG. 2 is a diagram schematically illustrating an IFD transceiver according to a second exemplary embodiment of the present invention.

FIG. 3 is a diagram schematically illustrating an IFD transceiver according to a third exemplary embodiment of the present invention.

FIG. 4 is a diagram schematically illustrating an IFD transceiver according to a fourth exemplary embodiment of the present invention.

FIG. 5 is a diagram schematically illustrating an IFD transceiver according to a fifth exemplary embodiment of the present invention.

FIG. 6 is a diagram schematically illustrating an IFD transceiver according to a sixth exemplary embodiment of the present invention.

FIG. 7 is a diagram schematically illustrating an IFD transceiver according to a seventh exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout the present specification and claims, unless explicitly described to the contrary, “comprising” any components will be understood to imply the inclusion of other elements rather than the exclusion of any other elements.

Throughout the specification, a terminal may refer to a mobile terminal (MT), a mobile station (MS), an advanced mobile station (AMS), a high reliability mobile station (HR-MS), a subscriber station (SS), a portable subscriber station (PSS), an access terminal (AT), user equipment (UE), and the like and may also include all or some of the functions of the MT, the MS, the AMS, the HR-MS, the SS, the PSS, the AT, the UE, and the like.

Further, the base station (BS) may refer to an advanced base station (ABS), a high reliability base station (HR-BS), a node B, an evolved node B (eNodeB), an access point (AP), a radio access station (RAS), a base transceiver station (BTS), a mobile multihop relay (MMR)-BS, a relay station (RS) serving as a base station, a relay node (RN) serving as a base station, an advanced relay station (ARS) serving as a base station, a high reliability relay station (HR-RS) serving as a base station, small base stations (a femto base station (femto BS), a home node B (HNB), a home eNodeB (HeNB), a pico base station (pico BS), a metro base station (metro BS), a micro base station (micro BS), and the like), and the like and may also include all or some of the functions of the ABS, the HR-BS, the node B, the eNodeB, the AP, the RAS, the BTS, the MMR-BS, the RS, the RN, the ARS, the HR-RS, the small base stations, and the like.

Throughout the specification, a transceiver may refer to a terminal, a mobile terminal (MT), a mobile station (MS), an advanced mobile station (AMS), a high reliability mobile station (HR-MS), a subscriber station (SS), a portable subscriber station (PSS), an access terminal (AT), user equipment (UE), and the like and may also include all or some of the functions of the terminal, the MT, the MS, the AMS, the HR-MS, the SS, the PSS, the AT, the UE, and the like.

Further, a transceiver may refer to a base station (BS), an advanced base station (ABS), a high reliability base station (HR-BS), a nodeB, an evolved node B (eNodeB), an access point (AP), a radio access station (RAS), a base transceiver station (BTS), a mobile multihop relay (MMR)-BS, a relay station (RS) serving as a base station, a high reliability relay station (HR-RS) serving as a base station, and the like and may also include all or some of the functions of the BS, the ABS, the HR-BS, the nodeB, the eNodeB, the AP, the RAS, the BTS, the MMR-BS, the RS, the HR-RS, and the like.

Hereinafter, an in-band full duplex (IFD) transceiver which may implement multiple-input multiple-output (MIMO) according to exemplary embodiments of the present inventions will be described in detail with reference to necessary drawings.

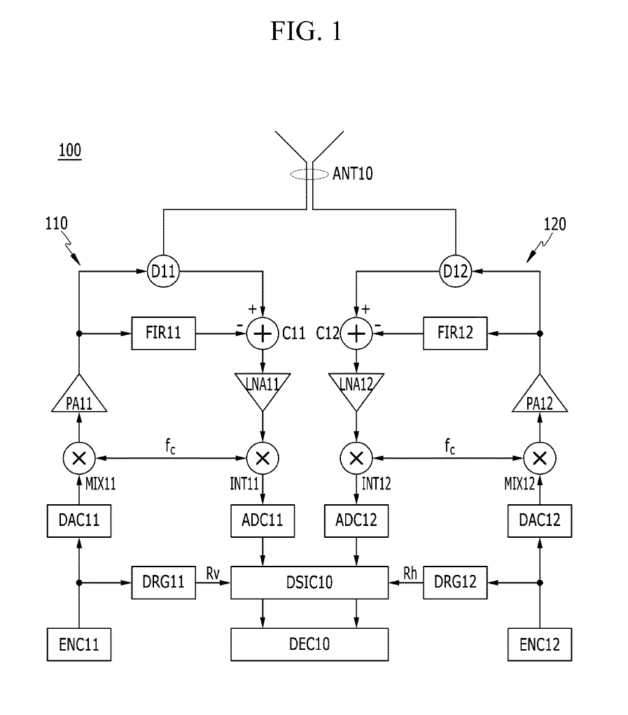

FIG. 1 is a diagram schematically illustrating an IFD transceiver according to a first exemplary embodiment of the present invention.

Referring to FIG. 1, an IFD transceiver 100 according to a first exemplary embodiment of the present invention may include one antenna ANT10 and a plurality of IFD transmitting/receiving modules 110 and 120 connected with the one antenna ANT10.

The antenna ANT10 is a multi polarized antenna which includes a plurality of polarized transmitting/receiving units transmitting/receiving different polarized signals. FIG. 1 illustrates, for example, that the antenna ANT10 is a dual polarized antenna including two polarized transmitting/receiving units (for example, vertical polarized transmitting/receiving unit and horizontal polarized transmitting/receiving unit).

Polarization of an electromagnetic wave is called a wave of an electric field component at any fixed point or fixed surface vertical to a propagation direction of the electromagnetic wave. In a wireless communication technology, radio waves radiated through antennas have unique polarization characteristics for each antenna. Linear polarization indicates polarization in which an electric field vector direction always vibrates only in a single one-dimensional direction. If the electromagnetic wave is horizontal to a ground, the electromagnetic wave is called horizontal polarization and if the electromagnetic wave is orthogonal to a ground, the electromagnetic wave is called vertical polarization.

The horizontal polarization and the vertical polarization are orthogonal to each other.

Each polarized transmitting/receiving unit of the antenna ANT10 may be connected to different IFD transmitting/receiving modules 110 and 120. For example, the IFD transmitting/receiving module 110 may be connected with the vertical polarized transmitting/receiving unit of the antenna ANT10 and the IFD transmitting/receiving module 120 may be connected with the horizontal polarized transmitting/receiving unit of the antenna ANT10.

The IFD transmitting/receiving modules 110 and 120 transmit/receive polarized signals independent of each other. For example, the IFD transmitting/receiving module 110 may transmit/receive a signal through the vertical polarized transmitting/receiving unit of the antenna ANT10 and the IFD transmitting/receiving module 120 may transmit/receive a signal through the horizontal polarized transmitting/receiving unit of the antenna 10.

Each of the IFD transmitting/receiving modules 110 and 120 may be configured of distributors D11 and D12, an analog circuit unit, and a digital circuit unit.

The distributors D11 and D12 are connected between the respective polarized transmitting/receiving units of the antenna ANT10 and the analog circuit units of the respective IFD transmitting/receiving modules 110 and 120.

Each of the distributors D11 and D12 transmits a transmitted signal to a transmitting path and transmits a received signal to a receiving path to serve to distribute the transmitted signal and the received signal. When receiving the transmitted signal from the analog circuit units (e.g., power amplifier (PA), etc.) of the respective IFD transmitting/receiving modules 110 and 120, the respective distributors D11 and D12 transmit the transmitted signal to the respective polarized transmitting/receiving units of the antenna ANT10. Further, when receiving the received signals from the respective polarized transmitting/receiving units of the antenna ANT10, the respective distributors D11 and D12 transmit the received signals to the analog circuit units (e.g., low noise amplifier (LNA), etc.) of the respective IFD transmitting/receiving modules 110 and 120.

As described above, the distributors D11 and D12 have characteristics of separating the transmitting path and the receiving path of the respective IFD transmitting/receiving modules 110 and 120 from each other. Due to the characteristics, the distributors D11 and D12 may serve self-interference cancellation (SIC) that suppresses self-interference (SI) from occurring. That is, since the transmitting path and the receiving path are separated from each other by the distributors D11 and D12, the occurrence of the SI that causes the interference of the transmitted signal transmitted along the transmitting path with the received signal transmitted along the receiving path may be suppressed. The SI means the interference of the transmitted signal of the IFD transceiver 100 with the received signal of the IFD transceiver 100 in the IFD transceiver 100. The SI may occur due to the flow of the signal transmitted through the antenna ANT10 of the IFD transceiver 100 into the antenna ANT10 of the IFD transceiver 100 and may also occur due to reflection, leakage, etc., on an internal circuit of the IFD transceiver 100.

Each of the IFD transmitting/receiving modules 110 and 120 uses the distributors D11 and D12 to simultaneously transmit/receive the signal through the antenna ANT10.

The distributors D11 and D12 may include a circulator, an electrical balance duplexer (EBD), etc. The EBD may include a hybrid transformer and a balance network.

When receiving analog received signals from the respective polarized transmitting/receiving units of the antenna ANT10, the analog circuit units of the respective IFD transmitting/receiving modules 110 and 120 serve to convert the analog received signal into the digital received signal. The received signals converted into the digital signals by the respective analog circuit units are transmitted to and processed by the corresponding digital circuit units.

To this end, the analog circuit units of the respective IFD transmitting/receiving modules 110 and 120 may include low noise amplifiers LNA11 and LNA12, integrators INT11 and INT12, and analog to digital converters ADC11 and ADC12.

The low noise amplifiers LNA11 and LNA 12 cancel noise from the analog received signals received through the respective polarized transmitting/receiving units of the antenna ANT10 and amplify the analog received signal from which the noise is canceled and output the amplified analog received signal to the integrators INT11 and INT12.

The integrators INT11 and INT12 receive the analog received signal in a radio frequency (RF) band and use a carrier frequency signal f_{C} to convert the analog received signal into an analog received signal in a baseband.

When receiving the analog received signals converted into the baseband from the integrators INT11 and INT12, the analog to digital converters ADC11 and ADC12 convert the analog received signals into the digital received signals and output the digital received signals to the digital circuit unit.

When receiving the digital transmitted signals from the corresponding digital circuit units, the analog circuit units of the respective IFD transmitting/receiving modules 110 and 120 serve to convert the digital transmitted signals into the analog transmitted signals. The distributors D11 and D12 transmit the transmitted signals converted into the analog signals by the respective analog circuit units to the respective polarized transmitting/receiving units of the antenna ANT10.

To this end, the analog circuit units of the respective IFD transmitting/receiving modules 110 and 120 may include digital to analog converters DAC11 and DAC12, mixers MIX11 and MIX12, and power amplifiers PA11 and PA12.

When receiving the digital transmitted signal from the digital circuit unit, the digital to analog converters DAC11 and DAC12 convert the digital transmitted signal into the analog transmitted signal in the baseband and output the analog transmitted signal.

When receiving the analog transmitted signal in the baseband from the digital to analog converters DAC11 and DAC12, the mixers MIX11 and MIX12 use the carrier frequency signal f_{C} to convert the analog transmitted signal into an analog transmitted signal in an RF band.

The power amplifiers PA11 and PA12 receive the analog received signals converted into the RF band from the respective mixers MIX11 and MIX12 and amplify and output the analog received signals.

The analog transmitted signals amplified by the respective power amplifiers PA11 and PA12 are transmitted to the respective polarized transmitting/receiving units of the antenna ANT10 through the distributors D11 and D12 and transmitted by the respective polarized transmitting/receiving units of the antenna ANT10.

The analog circuit units of the respective IFD transmitting/receiving modules 110 and 120 may include finite impulse response filters FIR11 and FIR12 and couplers C11 and C12 so as to cancel the SI that inflows without being canceled by the distributors D11 and D12 or occurs in the analog circuit unit.

The FIR filters FIR11 and FIR12 use the transmitted signals of the respective IFD transmitting/receiving modules 110 and 120 to generate an interference cancellation signal for canceling the SI occurring due to the transmitted signals of the IFD transmitting/receiving modules 110 and 120 in the respective IFD transmitting/receiving modules 110 and 120.

The FIR filters FIR11 and FIR12 receive the transmitted signals of the respective IFD transmitting/receiving modules 110 and 120 from the power amplifiers PA11 and PA12 of the respective IFD transmitting/receiving modules 110 and 120 and generate the interference cancellation signals of the respective IFD transmitting/receiving modules 110 and 120 from the transmitted signals. The interference cancellation signals generated by the FIR filters FIR11 and FIR12 are input to the couplers C11 and C12 of the corresponding IFD transmitting/receiving modules 110 and 120.

The couplers C11 and C12 are connected between the distributors D11 and D12 and the low noise amplifiers LNA11 and LNA12 to receive the received signals from the distributors D11 and D12.

When receiving the received signals from the respective distributors D11 and D12, the couplers C11 and C12 use the interference cancellation signals generated from the FIR filters FIR11 and FIR12 to cancel the SI from the received signals and output the received signals. That is, each of the couplers C11 and C12 couples the received signals transmitted through the respective distributors D11 and D12 with the interference cancellation signal input from the FIR filters FIR11 and FIR12 to cancel the SI from the received signals and then outputs the received signals.

The received signals from which the SI is canceled by the couplers C11 and C12 are output to the low noise amplifiers LAN11 and LNA12.

When receiving the digital received signals from the analog circuit units, the digital circuit units of the respective IFD transmitting/receiving modules 110 and 120 decode the digital received signals to output received data. Further, when receiving transmitted data, the digital circuit units of the respective IFD transmitting/receiving modules 110 and 120 encode the transmitted data to output the digital transmitted signal.

To this end, the digital circuit units of the respective IFD transmitting/receiving modules 110 and 120 may include a decoder DEC10 and encoders ENC11 and ENC12.

When receiving the analog received signals from the analog circuit units (for example, analog digital converters ADC11 and ADC12) of the respective IFD transmitting/receiving modules 110 and 120, the decoder DEC10 decodes the analog received signals to output the corresponding received data.

When receiving the transmitted data corresponding to the respective IFD transmitting/receiving modules 110 and 120, the encoders ENC11 and ENC12 encode the transmitted data to generate the digital transmitting signals. The digital transmitted signals generated by the encoders ENC11 and ENC12 are transmitted to the analog circuit units (e.g., digital to analog converters DAC11 and DAC21) of the respective IFD transmitting/receiving modules 110 and 120.

The digital circuit units of the IFD transmitting/receiving modules 110 and 120 may include a digital self-interference canceller DSIC10 for canceling the SI that flows in the digital circuit unit without being canceled by the analog circuit unit or occurring in the digital circuit unit and digital reference generators DRG11 and DRG12.

The digital interference canceller DSIC10 may be connected between the analog circuit unit (e.g., analog to digital converters ADC11 and ADC12) of the IFD transmitting/receiving modules 110 and 120 and the decoder DEC10.

The digital interference canceller DSIC10 uses the digital transmitted signals of the respective IFD transmitting/receiving modules 110 and 120 to cancel the remaining SI from the digital received signals transmitted from the respective analog circuit units (e.g., analog to digital converters ADC11 and ADC12) to the decoder DEC10.

The digital received signals input from the analog circuit units of the respective IFD transmitting/receiving modules 110 and 120 to the digital interference canceller DSIC10 may be distorted due to elements (distributor, adder, low noise amplifier, analog to digital converter, etc.) configuring the receiving path while they pass through the antenna, the distributor, the analog circuit unit, etc. Therefore, the SI component of the transmitted signal flowing in the received signal is also input to the digital circuit unit while being distorted while it passes through the receiving path.

Meanwhile, as illustrated in FIG. 1, when receiving the digital transmitted signal used in the digital SIC from the encoders ENC11 and ENC12, the digital interference canceller DSIC10 may not sufficiently cancel the SI component distorted while passing through the receiving path.

Therefore, each of the digital reference generators DRG11 and DRG12 distorts the digital transmitted signals output from the respective encoders ENC11 and ENC12 to be similar to the distortion on the receiving path and outputs the distorted digital transmitted signals to the digital interference canceller DSIC10. Further, the digital interference canceller DSIC10 uses digital transmitted signals Rv and Rh distorted by the respective digital reference generators DRG11 and DRG12 to perform the digital SIC.

Meanwhile, FIG. 1 illustrates, for example, the case in which the IFD transmitting/receiving modules 110 and 120 share the digital interference canceller DSIC10 and the decoder DEC10, but the present invention is not limited thereto. Therefore, the digital interference canceller DSIC10 and the decoder DEC10 may also be separately implemented for each IFD transmitting/receiving module 110 and 120.

The IFD transceiver 100 according to the first exemplary embodiment of the present invention having the foregoing structure may be operated as a 2×2 MIMO transceiver. The dual polarized antenna ANT10 may simultaneously transmit/receive two different polarized signals through two polarized transmitting/receiving units. Therefore, when the IFD transceiver 100 uses the polarized signal to obtain a multiplexing gain or polarized diversity, 2×2 MIMO may be implemented only by a single dual polarized antenna.

Therefore, when two communication nodes multiplex different data into the vertical polarized signal and the horizontal polarized signal through the IFD transceiver 100 according to the first exemplary embodiment of the present invention and exchange the data, it is possible to secure link capacity up to four times as high as a single input single output (SISO) transceiver operated in a half duplex (HD) mode and up to twice as high as the SISO transceiver operated in an IFD mode.

Meanwhile, when the MIMO IFD transceiver is implemented using a plurality of general antennas, not using the polarized antenna, if a distance between the antennas is not sufficiently secured, the FIR filter corresponding to a square of then number of antennas needs to be used to cancel the SI in the analog circuit unit. When the distance between the antennas is not sufficient, the received signal received through the respective antennas also includes the SI of the transmitted signals transmitted from other antennas as well as the SI of the transmitted signal transmitted from corresponding antenna. Therefore, to perform the analog SIC from the received signals of the respective antennas, the FIR filter is required as many as the number of paths through which the SI flows in each antenna, that is, the number of antennas of the IFD transceiver. For example, in the MIMO IFD transceiver using two antennas, four adaptive FIR filters are used to cancel the SI from the analog circuit unit.

On the other hand, in the IFD transceiver 100 according to the first exemplary embodiment of the present invention, only one adaptive FIR filter FIR11 and FIR12 is used for each polarized transmitting/receiving unit of the antenna ANT10. The reason is that the SI inflowing from other polarized transmitting/receiving units of the antenna ANT10 inflows while having reduced power enough to be canceled by SIC of the digital circuit unit due to a separated gain of the dual polarized antenna ANT10, and therefore the analog circuit unit is enough to cancel only its own SI using one adaptive FIR filter for each polarized transmitting/receiving unit.

Meanwhile, the first exemplary embodiment of the present invention illustrates, for example, the case in which the antenna is the dual polarized antenna including two different polarized transmitting/receiving units but the present invention is not limited thereto. Therefore, according to another exemplary embodiment of the present invention, the number of polarized transmitting/receiving units configuring the antenna may also more increased. In this case, the IFD transceiver may further include the IFD transmitting/receiving module corresponding to the added polarized transmitting/receiving unit. For example, when the antenna is a tri polarized antenna, the antenna may include three polarized transmitting/receiving units and the MIMO IFD transceiver may include three IFD transmitting/receiving modules connected with the three polarized transmitting/receiving units, respectively.

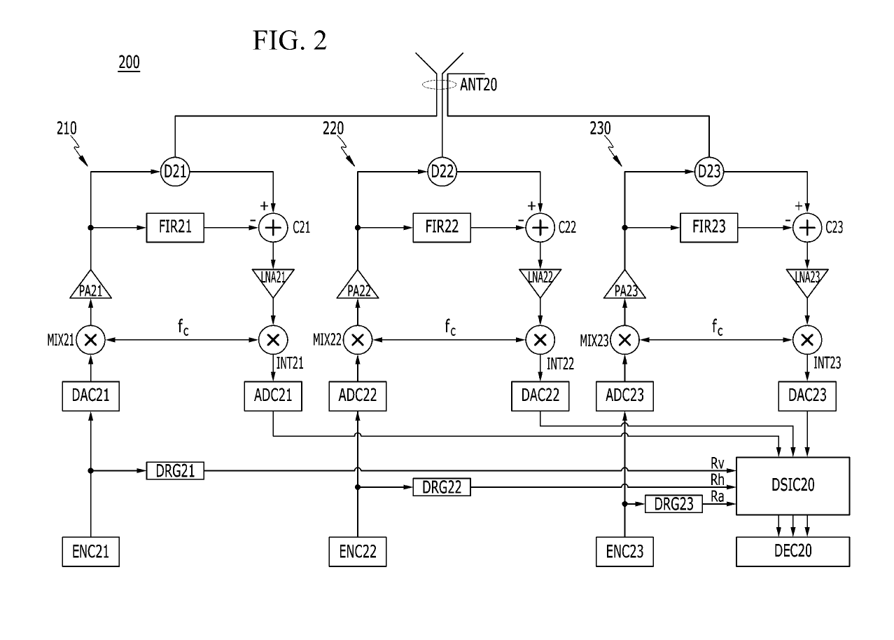

FIG. 2 is a diagram schematically illustrating an IFD transceiver according to a second exemplary embodiment of the present invention.

Referring to FIG. 2, an IFD transceiver 200 according to a second exemplary embodiment of the present invention may include one tri polarized antenna ANT20 and a plurality of IFD transmitting/receiving modules 210, 220, and 230 connected with the one antenna ANT20.

The tri polarized antenna ANT20 includes three polarized transmitting/receiving units transmitting/receiving three different polarizations (e.g., vertical polarization, horizontal polarization, azimuth polarization).

The IFD transceiver 200 according to the second exemplary embodiment of the present invention uses the tri polarized antenna ANT20 and therefore may include the three IFD transmitting/receiving modules 210, 220, and 230 connected to the respective polarized transmitting/receiving units of the tri polarized antenna ANT20. For example, the IFD transceiver 200 may include the IFD transmitting/receiving module 210 connected to the vertical polarized transmitting/receiving unit of the tri polarized antenna ANT20, the IFD transmitting/receiving module 220 connected with the horizontal polarized transmitting/receiving unit, and the IFD transmitting/receiving module 230 connected to the azimuth polarized transmitting/receiving unit.

The IFD transmitting/receiving modules 210, 220, and 230 transmit/receive polarized signals independent of each other. For example, the IFD transmitting/receiving module 210 may transmit/receive a signal through the vertical polarized transmitting/receiving unit of the tri polarized antenna ANT20, the IFD transmitting/receiving module 220 may transmit/receive a signal through the horizontal polarized transmitting/receiving unit of the tri polarized antenna ANT20, and the IFD transmitting/receiving module 230 may transmit/receive a signal through the azimuth polarized transmitting/receiving unit of the tri polarized antenna ANT20.

Each of the IFD transmitting/receiving modules 210, 220, and 230 may include one of distributors D21, D22, and D23, the analog circuit unit, and the digital circuit unit.

Meanwhile, operations of each component (distributors D21, D22, and D23, low noise amplifiers LNA21, LAN22, and LNA23, integrators INT21, INT22, and INT23, digital to analog converters DAC21, DAC22, and DAC23, mixers MIX21, MIX22, and MIX23, power amplifiers PA21, PA22, and P23, FIR filters FIR21, FIR22, and FIR23, couplers C21, C22, and C23, a decoder DEC20, encoders ENC21, ENC22, and ENC23, a digital interference canceller DSIC20, and digital reference generators DRG21, DRG22, and DRG23) configuring the respective IFD transmitting/receiving modules 210, 220, and 230 are the same as the operations of each component configuring the IFD transmitting/receiving modules 110 and 120 according to the foregoing first exemplary embodiment of the present invention, and therefore to avoid the overlapping description below, the detailed description of each component configuring the respective IFD transmitting/receiving modules 210, 220, and 230 will be omitted.

FIG. 2 illustrates, for example, the case in which the IFD transmitting/receiving modules 210, 220, and 230 share the digital interference canceller DSIC20 and the decoder DEC20, but the present invention is not limited thereto. Therefore, the digital interference canceller and the decoder may also be separately implemented for each IFD transmitting/receiving modules 210, 220, and 230.

The IFD transceiver 200 according to the second exemplary embodiment of the present invention having the foregoing structure may be operated as a 3×3 MIMO transceiver. The tri polarized antenna ANT20 may simultaneously transmit/receive three different polarized signals through three polarized transmitting/receiving units. Therefore, when the IFD transceiver 200 uses the polarized signal to obtain the multiplexing gain or the polarized diversity, 3×3 MIMO may be implemented only by a single tri polarized antenna.

Therefore, when two communication nodes multiplex different data into the vertical polarized signal, the horizontal polarized signal, and the azimuth polarized signal through the IFD transceiver 200 according to the second exemplary embodiment of the present invention and exchange the data, it is possible to secure the link capacity up to six times as high as the SISO transceiver operated in the HD mode and up to three times as high as the SISO transceiver operated in the IFD mode.

In the IFD transceiver 200 according to the second exemplary embodiment of the present invention, only one of the adaptive FIR filters FIR21, FIR22, and FIR23 is used in each polarized transmitting/receiving unit of the tri polarized antenna ANT20 for the SIC, and therefore only a total of three FIR filter is used for the SIC in the analog circuit unit. The reason is that the SI inflowing from other polarized transmitting/receiving units of the antenna ANT20 inflows while having reduced power enough to be canceled by the SIC of the digital circuit unit due to a separated gain of the tri polarized antenna ANT20, and therefore the analog circuit unit is enough to cancel only its own SI using one adaptive FIR filter for each polarized transmitting/receiving unit.

As described above, the IFD transceivers 100 and 200 according to the first and second exemplary embodiments of the present invention implement the MIMO using only a single multi polarized antenna. Further, due to characteristics of the multi polarized antenna, the FIR filter used to cancel the interference between different polarized transmitting/receiving units is omitted. Therefore, the complexity of the MIMO IFD transceivers 100 and 200 is remarkably reduced.

Meanwhile, the first and second exemplary embodiments of the present invention illustrate, for example, the case in which the MIMO IFD transceiver is implemented using a single multi polarized antenna, but the present invention is not limited thereto. Therefore, the IFD transceiver according to another exemplary embodiment of the present invention may also include a plurality of multi polarized antennas to increase the link capacity. In this case, the IFD transceivers may further include the FIR filter to cancel the interference between the antennas.

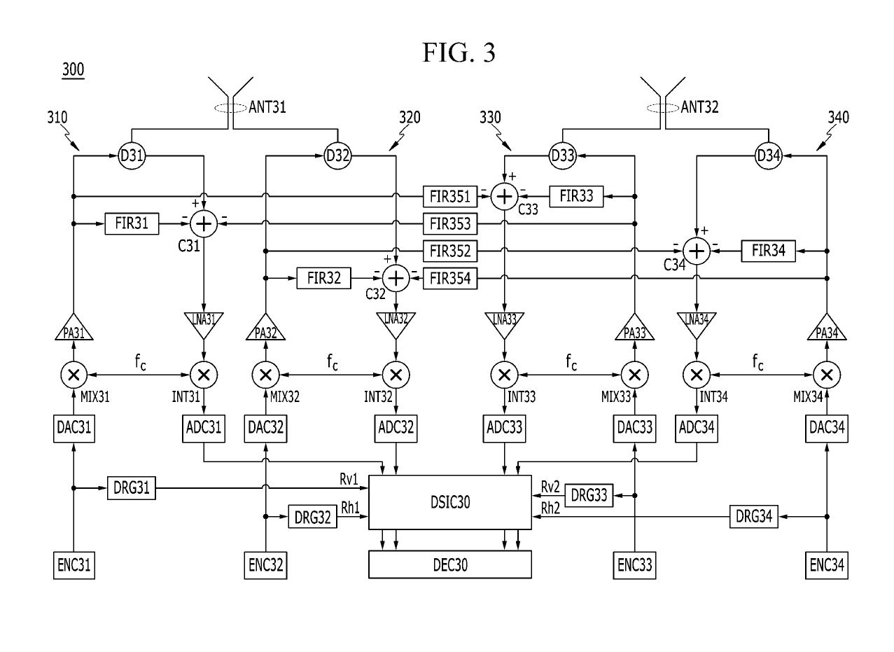

FIG. 3 is a diagram schematically illustrating an IFD transceiver according to a third exemplary embodiment of the present invention.

Referring to FIG. 3, an IFD transceiver 300 according to a third exemplary embodiment of the present invention may include a plurality of dual polarized antennas ANT31 and ANT32 and a plurality of IFD transmitting/receiving modules 310, 320, 330, and 340 connected with the plurality of antennas ANT31 and ANT32.

The respective dual polarized antennas ANT31 and ANT32 include two polarized transmitting/receiving units transmitting/receiving two different polarizations (for example, vertical polarization, horizontal polarization).

The IFD transmitting/receiving modules 310, 320, 330, and 340 are each connected to the polarized transmitting/receiving units configuring the respective dual polarized antennas ANT31 and ANT32.

In FIG. 3, the IFD transceiver 300 includes the two dual polarized antennas ANT31 and ANT32, and therefore includes four IFD transmitting/receiving modules 310, 320, 330, and 340. That is, the IFD transceiver 300 may include the IFD transmitting/receiving module 310 connected to the vertical polarized transmitting/receiving unit of the dual polarized antenna ANT31, the IFD transmitting/receiving module 320 connected to the horizontal polarized transmitting/receiving unit of the dual polarized antenna ANT31, the IFD transmitting/receiving module 330 connected to the vertical polarized transmitting/receiving unit of the dual polarized antenna ANT32, and the IFD transmitting/receiving module 340 connected to the horizontal polarized transmitting/receiving unit of the dual polarized antenna ANT32.

The IFD transmitting/receiving modules 310, 320, 330, and 340 transmit/receive polarized signals independent of each other. For example, the IFD transmitting/receiving module 310 may transmit/receive a signal through the vertical polarized transmitting/receiving unit of the dual polarized antenna ANT31 and the IFD transmitting/receiving module 320 may transmit/receive a signal through the horizontal polarized transmitting/receiving unit of the dual polarized antenna ANT31.

Further, the IFD transmitting/receiving module 330 may transmit/receive a signal through the vertical polarized transmitting/receiving unit of the dual polarized antenna ANT32 and the IFD transmitting/receiving module 340 may transmit/receive a signal through the horizontal polarized transmitting/receiving unit of the dual polarized antenna ANT32.

Each of the IFD transmitting/receiving modules 310, 320, 330, and 340 may include one of distributors D31, D32, D33, and D34, the analog circuit unit, and the digital circuit unit.

Meanwhile, to avoid the overlapping description, the detailed description of some components (distributors D31, D32, D33, and D34, low noise amplifiers LNA31, LNA32, LNA33, and LNA34, integrators INT31, INT32, INT33, and INT34, digital to analog converters DAC31, DAC32, DAC33, and DAC34, mixers MIX31, MIX32, MIX33, and MIX34, power amplifiers PA31, PA32, PA33, and PA34, FIR filters FIR31, FIR32, FIR33, and FIR34, a decoder DEC30, encoders ENC31, ENC32, ENC33, and ENC34, a digital interference canceller DSIC30, and digital reference generators DRG31, DRG32, DRG33, and DRG34) performing the same function as the components of the IFD transmitting/receiving modules 110 and 120 according to the first exemplary embodiment of the present invention among the components configuring the respective IFD transmitting/receiving modules 310, 320, 330, and 340 will be omitted below.

FIG. 3 illustrates, for example, the case in which the IFD transmitting/receiving modules 310, 320, 330, and 340 share the digital interference canceller DSIC30 and the decoder DEC30, but the present invention is not limited thereto. Therefore, the digital interference canceller and the decoder may also be separately implemented for each IFD transmitting/receiving modules 310, 320, 330, and 340.

Meanwhile, when the distance between the dual polarized antennas ANT31 and ANT32 is not sufficient, the IFD transceiver 300 according to the third exemplary embodiment of the present invention may cause the interference between the dual polarized antennas ANT31 and ANT32. That is, when the distance between the dual polarized antennas ANT31 and ANT32 is not sufficient, the transmitted signal transmitted through the dual polarized antenna ANT31 causes the interference with the received signal of the dual polarized antenna ANT32 or the transmitted signal transmitted through the dual polarized antenna ANT32 causes the interference with the received signal of the dual polarized antenna ANT31.

Therefore, the IFD transceiver 300 according to the third exemplary embodiment of the present invention may further include a plurality of FIR filters FIR351, FIR352, FIR353, and FIR354 to cancel the interference between the antennas ANT31 and ANT32.

The FIR filters FIR351, FIR352, FIR353, and FIR354 generate the interference cancellation signal to cancel the interference between the polarized transceivers transmitting/receiving the same polarization.

For example, the FIR filter FIR351 generates the interference cancellation signal for canceling the interference occurring due to the transmitted signal transmitted through the vertical polarized transmitting/receiving unit of the dual polarized antenna ANT31 from the received signal received through the vertical polarized transmitting/receiving unit of the dual polarized antenna ANT32. Further, for example, the FIR filter FIR352 generates the interference cancellation signal for canceling the interference occurring due to the transmitted signal transmitted through the horizontal polarized transmitting/receiving unit of the dual polarized antenna ANT31 from the received signal received through the horizontal polarized transmitting/receiving unit of the dual polarized antenna ANT32. Further, for example, the FIR filter FIR353 generates the interference cancellation signal for canceling the interference occurring due to the transmitted signal transmitted through the vertical polarized transmitting/receiving unit of the dual polarized antenna ANT32 from the received signal received through the vertical polarized transmitting/receiving unit of the dual polarized antenna ANT31. Further, for example, the FIR filter FIR354 generates the interference cancellation signal for canceling the interference occurring due to the transmitted signal transmitted through the horizontal polarized transmitting/receiving unit of the dual polarized antenna ANT32 from the received signal received through the horizontal polarized transmitting/receiving unit of the dual polarized antenna ANT31.

The interference cancellation signals generated by the FIR filters FIR351, FIR352, FIR353, and FIR354 are input to the respective couplers C31, C32, C33, and C34. For example, the interference cancellation signal generated by the FIR filter FIR351 may be input to the coupler C33, the interference cancellation signal generated by the FIR filter FIR352 may be input to the coupler C34, the interference cancellation signal generated by the FIR filter FIR353 may be input to the coupler C31, and the interference cancellation signal generated by the FIR filter FIR354 may be input to the coupler C32.

The couplers C31, C32, C33, and C34 receive the interference cancellation signals for canceling the SI occurring due to the transmitted signals of their own IFD transmitting/receiving modules from the FIR filters FIR31, FIR32, FIR33, and FIR34. Further, the couplers C31, C32, C33, and C34 receive the interference cancellation signals for canceling the SI occurring due to the transmitted signal of other antennas from the FIR filters FIR351, FIR352, FIR353, and FIR354.

When receiving the received signals from the respective distributors D31, D32, D33, and D34, the couplers C31, C32, C33, and C34 use the interference cancellation signals input from the FIR filters FIR31, FIR32, FIR33, and FIR34 and the interference cancellation signals input from the FIR filters FIR351, FIR352, FIR353, and FIR354 to cancel the SI from the received signals and output the received signals.

As described above, in the IFD transceiver 300 according to the third exemplary embodiment of the present invention, the FIR filter is just used to cancel the interference between the polarized transceivers transmitting/receiving the same polarization as each other. The reason is that the SI inflowing from the polarized transmitting/receiving unit transmitting/receiving different polarizations inflows while having reduced power enough to be canceled by the SIC of the digital circuit unit due to the separated gain of the polarized antenna.

Therefore, in the IFD transceiver 300 according to the third exemplary embodiment of the present invention, the respective IFD transmitting/receiving modules 310, 320, 330, and 340 require only a total of two FIR filters of the FIR filter for canceling the SI occurring due to their own transmitted signals and the FIR filter for canceling the SI occurring due to the transmitted signal of the polarized transmitting/receiving unit transmitting/receiving the same polarizations as their own from other antennas. Therefore, the IFD transceiver 300 according to the third exemplary embodiment of the present invention uses only a total of eight FIR filters to cancel the SI.

The IFD transceiver 300 according to the third exemplary embodiment of the present invention having the foregoing structure may be operated as a 4×4 MIMO transceiver. Both of the two dual polarized antennas ANT31 and ANT32 may simultaneously transmit/receive four polarized signals through four polarized transmitting/receiving units. Therefore, when the IFD transceiver 300 uses the polarized signal to obtain the multiplexing gain or the polarized diversity, the 4×4 MIMO may be implemented only by the two dual polarized antennas.

Therefore, when two communication nodes multiplex different data into the vertical polarized signal and the horizontal polarized signal through the IFD transceiver 300 according to the third exemplary embodiment of the present invention and exchange the data, it is possible to secure the link capacity up to eight times as high as the SISO transceiver operated in the HD mode and up to four times as high as the SISO transceiver operated in the IFD mode.

Meanwhile, FIG. 3 illustrates, for example, the case in which the IFD transceiver 300 includes the two dual polarized antennas ANT31 and ANT32, but the present invention is not limited thereto. Therefore, the IFD transceiver 300 may be modified to include more dual polarized antennas. In this case, the IFD transceiver 300 may include 2×N (here, N is the number of dual polarized antennas) IFD transmitting/receiving modules and 2N² FIR filters. Further, the IFD transceiver 300 may be operated as 2N×2N MIMO transceivers to secure link capacity up to 4N times as high as the SISO transceiver operated in the HD mode and up to 2N times as high as the SISO transceiver operated in the IFD mode.

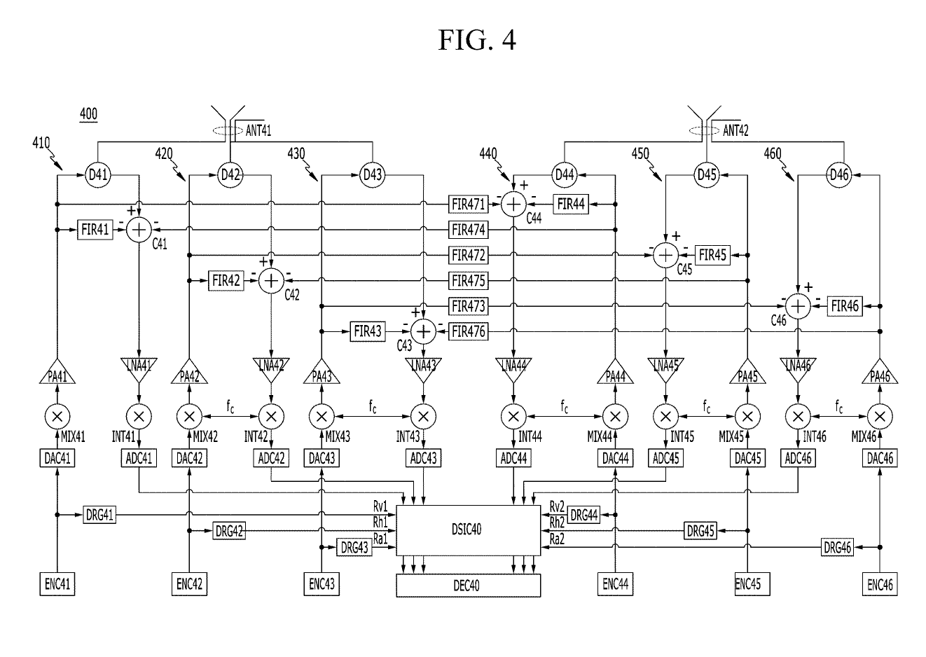

FIG. 4 is a diagram schematically illustrating an IFD transceiver according to a fourth exemplary embodiment of the present invention.

Referring to FIG. 4, an IFD transceiver 400 according to a fourth exemplary embodiment of the present invention may include a plurality of tri polarized antennas ANT41 and ANT42 and a plurality of IFD transmitting/receiving modules 410, 420, 430, 440, 450, and 460 connected with the plurality of antennas ANT41 and ANT42.

Each of the tri polarized antennas ANT41 and ANT42 includes three polarized transmitting/receiving units transmitting/receiving three different polarizations (e.g., vertical polarization, horizontal polarization, azimuth polarization).

The IFD transmitting/receiving modules 410, 420, 430, 440, 450, and 460 are each connected to the polarized transmitting/receiving units configuring the respective tri polarized antennas ANT41 and ANT42.

In FIG. 4, the IFD transceiver 400 includes the two tri polarized antennas ANT31 and ANT32, and therefore includes six IFD transmitting/receiving modules 410, 420, 430, 440, 450, and 460. That is, the IFD transceiver 400 may include the IFD transmitting/receiving module 410 connected with the vertical polarized transmitting/receiving unit of the tri polarized antenna ANT 41, the IFD transmitting/receiving module 420 connected with the horizontal polarized transmitting/receiving unit of the tri polarized antenna ANT 41, the IFD transmitting/receiving module 430 connected with the azimuth polarized transmitting/receiving unit of the tri polarized antenna ANT 41, the IFD transmitting/receiving module 440 connected with the vertical polarized transmitting/receiving unit of the tri polarized antenna ANT 42, the IFD transmitting/receiving module 450 connected with the horizontal polarized transmitting/receiving unit of the tri polarized antenna ANT 42, and the IFD transmitting/receiving module 460 connected with the azimuth polarized transmitting/receiving unit of the tri polarized antenna ANT 42.

The IFD transmitting/receiving modules 410, 420, 430, 440, 450, and 460 transmit/receive polarized signals independent of each other. For example, the IFD transmitting/receiving module 410 may transmit/receive a signal through the vertical polarized transmitting/receiving unit of the tri polarized antenna ANT41, the IFD transmitting/receiving module 420 may transmit/receive a signal through the horizontal polarized transmitting/receiving unit of the tri polarized antenna ANT41, and the IFD transmitting/receiving module 430 may transmit/receive a signal through the azimuth polarized transmitting/receiving unit of the tri polarized antenna ANT41. Further, the IFD transmitting/receiving module 440 may transmit/receive a signal through the vertical polarized transmitting/receiving unit of the tri polarized antenna ANT42, the IFD transmitting/receiving module 450 may transmit/receive a signal through the horizontal polarized transmitting/receiving unit of the tri polarized antenna ANT42, and the IFD transmitting/receiving module 460 may transmit/receive a signal through the azimuth polarized transmitting/receiving unit of the tri polarized antenna ANT42.

Each of the IFD transmitting/receiving modules 410, 420, 430, 440, 450, and 460 may include one of distributors D41, D42, D43, D44, D45, and D46, the analog circuit unit, and the digital circuit unit.

Meanwhile, to avoid the overlapping description, the detailed description of some components (distributors D41, D42, D43, D44, D45, and D46, low noise amplifiers LNA41, LNA42, LNA43, LNA44, LNA45, and LNA46, integrators INT41, INT42, INT43, INT44, INT45, and INT46, digital to analog converters DAC41, DAC42, DAC43, DAC44, DAC45, and DAC46, mixers MIX41, MIX42, MIX43, MIX44, MIX45, and MIX46, power amplifiers PA41, PA42, PA43, PA44, PA45, and PA46, FIR filters FIR41, FIR42, FIR43, FIR44, FIR45, and FIR46, a decoder DEC40, encoders ENC41, ENC42, ENC43, ENC44, ENC45, and ENC46, a digital interference canceller DSIC40, and digital reference generators DRG41, DRG42, DRG43, DRG44, DRG45, and DRG46) performing the same function as the components of the IFD transmitting/receiving modules 110 and 120 according to the first exemplary embodiment of the present invention among the components configuring the respective IFD transmitting/receiving modules 410, 420, 430, 440, 450, and 460 will be omitted below.

FIG. 4 illustrates, for example, the case in which the IFD transmitting/receiving modules 410, 420, 430, 440, 450, and 460 share the digital interference canceller DSIC40 and the decoder DEC40, but the present invention is not limited thereto. Therefore, the digital interference canceller and the decoder may also be separately implemented for each IFD transmitting/receiving modules 410, 420, 430, 440, 450, and 460.

Meanwhile, when the distance between the tri polarized antennas ANT41 and ANT42 is not sufficient, the IFD transceiver 400 according to the fourth exemplary embodiment of the present invention may cause the interference between the tri polarized antennas ANT41 and ANT42. That is, when the distance between the tri polarized antennas ANT41 and ANT42 is not sufficient, the transmitted signal transmitted through the tri polarized antenna ANT41 causes the interference with the received signal of the tri polarized antenna ANT42 or the transmitted signal transmitted through the tri polarized antenna ANT42 causes the interference with the received signal of the tri polarized antenna ANT41.

Therefore, the IFD transceiver 400 according to the fourth exemplary embodiment of the present invention may further include a plurality of FIR filters FIR471, FIR472, FIR473, FIR474, FIR475, and FIR476 to cancel the interference between the antennas ANT41 and ANT42.

The FIR filters FIR471, FIR472, FIR473, FIR474, FIR475, and FIR476 generate the interference cancellation signal to cancel the interference between the polarized transceivers transmitting/receiving the same polarization.

For example, the FIR filter FIR471 generates the interference cancellation signal for canceling the interference occurring due to the transmitted signal transmitted through the vertical polarized transmitting/receiving unit of the tri polarized antenna ANT41 from the received signal received through the vertical polarized transmitting/receiving unit of the tri polarized antenna ANT42. Further, for example, the FIR filter FIR472 generates the interference cancellation signal for canceling the interference occurring due to the transmitted signal transmitted through the horizontal polarized transmitting/receiving unit of the tri polarized antenna ANT41 from the received signal received through the horizontal polarized transmitting/receiving unit of the tri polarized antenna ANT42. Further, for example, the FIR filter FIR473 generates the interference cancellation signal for canceling the interference occurring due to the transmitted signal transmitted through the azimuth polarized transmitting/receiving unit of the tri polarized antenna ANT41 from the received signal received through the azimuth polarized transmitting/receiving unit of the tri polarized antenna ANT42.

Further, for example, the FIR filter FIR474 generates the interference cancellation signal for canceling the interference occurring due to the transmitted signal transmitted through the vertical polarized transmitting/receiving unit of the tri polarized antenna ANT42 from the received signal received through the vertical polarized transmitting/receiving unit of the tri polarized antenna ANT41. Further, for example, the FIR filter FIR475 generates the interference cancellation signal for canceling the interference occurring due to the transmitted signal transmitted through the horizontal polarized transmitting/receiving unit of the tri polarized antenna ANT42 from the received signal received through the horizontal polarized transmitting/receiving unit of the tri polarized antenna ANT41. Further, for example, the FIR filter FIR476 generates the interference cancellation signal for canceling the interference occurring due to the transmitted signal transmitted through the azimuth polarized transmitting/receiving unit of the tri polarized antenna ANT42 from the received signal received through the azimuth polarized transmitting/receiving unit of the azimuth polarized antenna ANT41.

The interference cancellation signals generated by the FIR filters FIR471, FIR472, FIR473, FIR474, FIR475, and FIR476 are input to the respective couplers C41, C42, C43, C44, C45, and C46. For example, the interference cancellation signal generated by the FIR filter FIR471 may be input to the coupler C44, the interference cancellation signal generated by the FIR filter FIR472 may be input to the coupler C45, the interference cancellation signal generated by the FIR filter FIR473 may be input to the coupler C46, the interference cancellation signal generated by the FIR filter FIR474 may be input to the coupler C41, the interference cancellation signal generated by the FIR filter FIR475 may be input to the coupler C42, and the interference cancellation signal generated by the FIR filter FIR476 may be input to the coupler C43.

The couplers C41, C42, C43, C44, C45, and C46 receive the interference cancellation signals for canceling the SI occurring due to the transmitted signals of their own IFD transmitting/receiving modules from the FIR filters FIR41, FIR42, FIR43, FIR44, FIR45, and FIR46. The couplers C41, C42, C43, C44, C45, and C46 receive the interference cancellation signals for canceling the SI occurring due to the transmitted signals of other antennas from the FIR filters FIR471, FIR472, FIR473, FIR474, FIR475, and FIR476.

When receiving the received signals from the respective distributors D41, D42, D43, D44, D45, and D46, the couplers C41, C42, C43, C44, C45, and C46 use the interference cancellation signals input from the FIR filters FIR41, FIR42, FIR43, FIR44, FIR45, and FIR46 and the interference cancellation signals input from the FIR filters FIR471, FIR472, FIR473, FIR474, FIR475, and FIR476 to cancel the SI from the received signals and output the received signals.

As described above, in the IFD transceiver 400 according to the fourth exemplary embodiment of the present invention, the FIR filter is just used to cancel the interference between the polarized transceivers transmitting/receiving the same polarization as each other. The reason is that the SI inflowing from the polarized transmitting/receiving unit transmitting/receiving different polarizations inflows while having reduced power enough to be canceled by the SIC of the digital circuit unit due to the separated gain of the polarized antenna.

Therefore, in the IFD transceiver 400 according to the fourth exemplary embodiment of the present invention, the respective IFD transmitting/receiving modules 410, 420, 430, 440, 450, and 460 require only a total of two FIR filters of the FIR filter for canceling the SI occurring due to their own transmitted signals and the FIR filter for canceling the SI occurring due to the transmitted signal of the polarized transmitting/receiving unit transmitting/receiving the same polarizations as their own from other antennas. Therefore, the IFD transceiver 400 according to the fourth exemplary embodiment of the present invention uses only a total of twelve FIR filters to cancel the SI.

The IFD transceiver 400 according to the fourth exemplary embodiment of the present invention having the foregoing structure may be operated as a 6×6 MIMO transceiver. Both of the two tri polarized antennas ANT41 and ANT42 may simultaneously transmit/receive six polarized signals through six polarized transmitting/receiving units. Therefore, when the IFD transceiver 400 uses the polarized signal to obtain the multiplexing gain or the polarized diversity, 6×6 MIMO may be implemented only by the two tri polarized antennas.

Therefore, when two communication nodes multiplex different data into the vertical polarized signal, the horizontal polarized signal, and the azimuth polarized signal through the IFD transceiver 400 according to the fourth exemplary embodiment of the present invention and exchange the data, it is possible to secure the link capacity up to twelve times as high as the SISO transceiver operated in the HD mode and up to six times as high as the SISO transceiver operated in the IFD mode.

Meanwhile, FIG. 4 illustrates, for example, the case in which the IFD transceiver 400 includes the two tri polarized antennas ANT41 and ANT42, but the present invention is not limited thereto. Therefore, the IFD transceiver 400 may be modified to include more tri polarized antennas. In this case, the IFD transceiver 400 may include 3×N (here, N is the number of tri polarized antennas) IFD transmitting/receiving modules and 3N² FIR filters. Further, the IFD transceiver 400 may be operated as 3N×3N MIMO transceivers to secure link capacity up to 9N times as high as the SISO transceiver operated in the HD mode and up to 3N times as high as the SISO transceiver operated in the IFD mode.

Meanwhile, the third and fourth exemplary embodiments of the present invention describe, for example, the case in which when a plurality of multi polarized antennas are used, the FIR filter for canceling the SI between different multi polarized antennas is further included, but the present invention is not limited thereto. Therefore, even when the IFD transceiver uses the plurality of multi polarized antennas, the FIR filter for canceling the SI between different antennas may also be omitted. When the transmitting/receiving apparatus may sufficiently secure the distance between the respective antennas since the limitation in the size of the transceivers of a base station, a relay station, etc., of a cellular system is relatively small, the transmitting/receiving apparatus is designed to make the distance between the antennas sufficiently long and thus the SI inflowing from the transmitted signals of other antennas due to a signal attenuation on the basis of the distance between the antennas inflows while having the reduced power enough to be canceled by the SIC in the digital circuit unit. In this case, even when the IFD transceiver uses the plurality of multi polarized antennas, the FIR filter for canceling the SI between different antennas may be omitted.

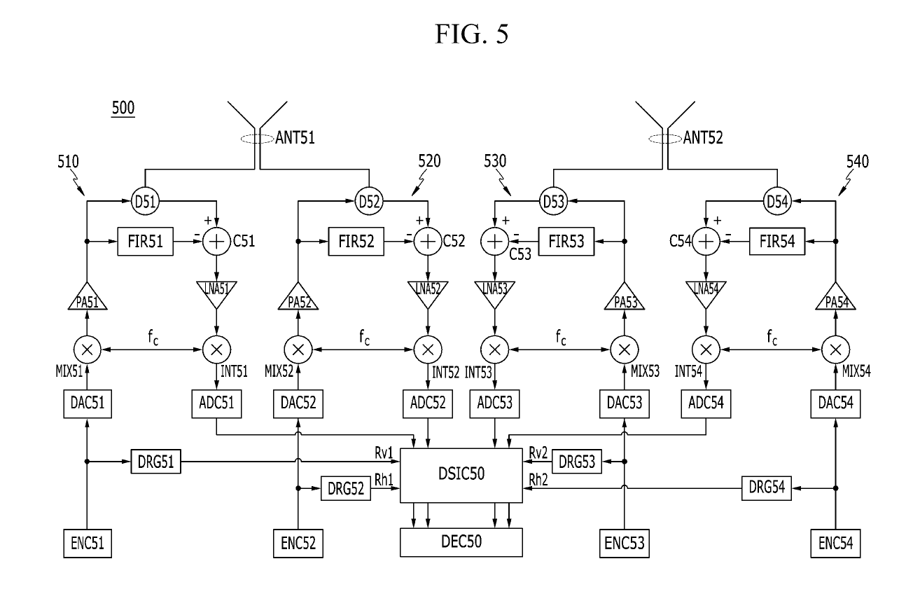

FIG. 5 is a diagram schematically illustrating an IFD transceiver according to a fifth exemplary embodiment of the present invention.

Referring to FIG. 5, an IFD transceiver 500 according to a fifth exemplary embodiment of the present invention may include a plurality of dual polarized antennas ANT51 and ANT52 and a plurality of IFD transmitting/receiving modules 510, 520, 530, and 540 connected with the plurality of antennas ANT51 and ANT52.

Each of the dual polarized antennas ANT51 and ANT52 includes two polarized transmitting/receiving units transmitting/receiving two different polarizations (e.g., vertical polarization, horizontal polarization).

The IFD transmitting/receiving modules 510, 520, 530, and 540 are each connected to the polarized transmitting/receiving units configuring the respective dual polarized antennas ANT51 and ANT52.

In FIG. 3, the IFD transceiver 500 includes the two dual polarized antennas ANT51 and ANT52, and therefore includes four IFD transmitting/receiving modules 510, 520, 530, and 540. That is, the IFD transceiver 500 may include the IFD transmitting/receiving module 510 connected to the vertical polarized transmitting/receiving unit of the dual polarized antenna ANT51, the IFD transmitting/receiving module 520 connected to the horizontal polarized transmitting/receiving unit of the dual polarized antenna ANT51, the IFD transmitting/receiving module 530 connected to the vertical polarized transmitting/receiving unit of the dual polarized antenna ANT52, and the IFD transmitting/receiving module 540 connected to the horizontal polarized transmitting/receiving unit of the dual polarized antenna ANT52.

The IFD transmitting/receiving modules 510, 520, 530, and 540 transmit/receive polarized signals independent of each other. For example, the IFD transmitting/receiving module 510 may transmit/receive a signal through the vertical polarized transmitting/receiving unit of the dual polarized antenna ANT51 and the IFD transmitting/receiving module 520 may transmit/receive a signal through the horizontal polarized transmitting/receiving unit of the dual polarized antenna ANT51. Further, the IFD transmitting/receiving module 530 may transmit/receive a signal through the vertical polarized transmitting/receiving unit of the dual polarized antenna ANT52 and the IFD transmitting/receiving module 540 may transmit/receive a signal through the horizontal polarized transmitting/receiving unit of the dual polarized antenna ANT52.

Each of the IFD transmitting/receiving modules 510, 520, 530, and 540 may include one of distributors D51, D52, D53, and D54, the analog circuit unit, and the digital circuit unit.

Meanwhile, to avoid the overlapping description, the detailed description of some components (distributors D51, D52, D53, and D54, low noise amplifiers LNA51, LNA52, LNA53, and LNA54, integrators INT51, INT52, INT53, and INT54, digital to analog converters DAC51, DAC52, DAC53, and DAC54, mixers MIX51, MIX52, MIX53, and MIX54, power amplifiers PA51, PA52, PA53, and PA54, FIR filters FIR51, FIR52, FIR53, and FIR54, a decoder DEC50, encoders ENC51, ENC52, ENC53, and ENC54, a digital interference canceller DSIC50, and digital reference generators DRG51, DRG52, DRG53, and DRG54) performing the same function as the components of the IFD transmitting/receiving modules 110 and 120 according to the first exemplary embodiment of the present invention among the components configuring the respective IFD transmitting/receiving modules 510, 520, 530, and 540 will be omitted below.

FIG. 5 illustrates, for example, the case in which the IFD transmitting/receiving modules 510, 520, 530, and 540 share the digital interference canceller DSIC50 and the decoder DEC50, but the present invention is not limited thereto. Therefore, the digital interference canceller and the decoder may also be separately implemented for each IFD transmitting/receiving modules 510, 520, 530, and 540.

Meanwhile, unlike the IFD transceiver 300 of FIG. 3, when the distance between the dual polarized antennas ANT51 and ANT52 is sufficiently secured, in the IFD transceiver 500 according to the fifth exemplary embodiment of the present invention, the FIR filter for canceling the interference between the antennas may be omitted.

Therefore, in the IFD transceiver 500 according to the fifth exemplary embodiment of the present invention, the respective IFD transmitting/receiving modules 510, 520, 530, and 540 include only one FIR filter for canceling the SI occurring due to their own transmitted signals. Therefore, the IFD transceiver 500 according to the fifth exemplary embodiment of the present invention uses only a total of four FIR filters to cancel the SI.

The IFD transceiver 500 according to the fifth exemplary embodiment of the present invention having the foregoing structure may be operated as a 4×4 MIMO transceiver. Both of the two dual polarized antennas ANT51 and ANT52 may simultaneously transmit/receive four polarized signals through four polarized transmitting/receiving units. Therefore, when the IFD transceiver 500 uses the polarized signal to obtain the multiplexing gain or the polarized diversity, the 4×4 MIMO may be implemented only by the two dual polarized antennas.

Therefore, when two communication nodes multiplex different data into the vertical polarized signal and the horizontal polarized signal through the IFD transceiver 500 according to the fifth exemplary embodiment of the present invention and exchange the data, it is possible to secure the link capacity up to eight times as high as the SISO transceiver operated in the HD mode and up to four times as high as the SISO transceiver operated in the IFD mode.

Meanwhile, FIG. 5 illustrates, for example, the case in which the IFD transceiver 500 includes the two dual polarized antennas ANT51 and ANT52, but the present invention is not limited thereto. Therefore, the IFD transceiver 500 may be modified to include more dual polarized antennas. In this case, the IFD transceiver 500 may include 2×N (here, N is the number of dual polarized antennas) IFD transmitting/receiving modules and 2N FIR filters. Further, the IFD transceiver 500 may be operated as 2N×2N MIMO transceivers to secure link capacity up to 4N times as high as the SISO transceiver operated in the HD mode and up to 2N times as high as the SISO transceiver operated in the IFD mode.

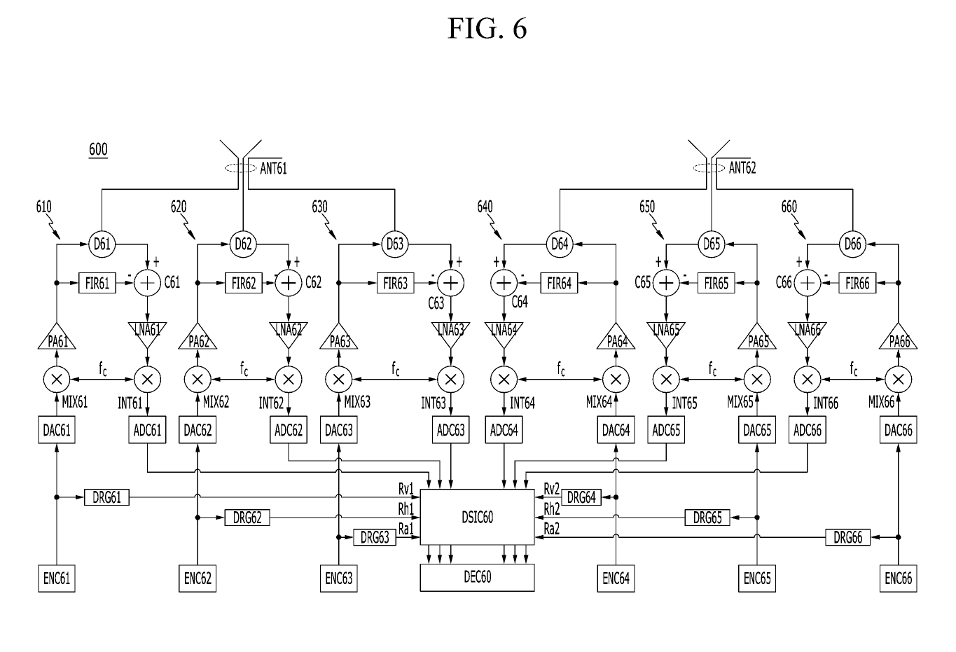

FIG. 6 is a diagram schematically illustrating an IFD transceiver according to a sixth exemplary embodiment of the present invention.

Referring to FIG. 6, an IFD transceiver 600 according to a sixth exemplary embodiment of the present invention may include a plurality of tri polarized antennas ANT61 and ANT62 and a plurality of IFD transmitting/receiving modules 610, 620, 630, 640, 650, and 660 connected with the plurality of antennas ANT61 and ANT62.

Each of the tri polarized antennas ANT61 and ANT62 includes three polarized transmitting/receiving units transmitting/receiving three different polarizations (e.g., vertical polarization, horizontal polarization, azimuth polarization).

The IFD transmitting/receiving modules 610, 620, 630, 640, 650, and 660 are each connected to the polarized transmitting/receiving units configuring the respective tri polarized antennas ANT61 and ANT62.

In FIG. 6, the IFD transceiver 600 includes the two tri polarized antennas ANT31 and ANT32, and therefore includes six IFD transmitting/receiving modules 610, 620, 630, 640, 650, and 660. That is, the IFD transceiver 600 may include the IFD transmitting/receiving module 610 connected with the vertical polarized transmitting/receiving unit of the tri polarized antenna ANT 61, the IFD transmitting/receiving module 620 connected with the horizontal polarized transmitting/receiving unit of the tri polarized antenna ANT 61, the IFD transmitting/receiving module 630 connected with the azimuth polarized transmitting/receiving unit of the tri polarized antenna ANT 61, the IFD transmitting/receiving module 640 connected with the vertical polarized transmitting/receiving unit of the tri polarized antenna ANT 62, the IFD transmitting/receiving module 650 connected with the horizontal polarized transmitting/receiving unit of the tri polarized antenna ANT 62, and the IFD transmitting/receiving module 660 connected with the azimuth polarized transmitting/receiving unit of the tri polarized antenna ANT 62.

The IFD transmitting/receiving modules 610, 620, 630, 640, 650, and 660 transmit/receive polarized signals independent of each other. For example, the IFD transmitting/receiving module 610 may transmit/receive a signal through the vertical polarized transmitting/receiving unit of the tri polarized antenna ANT61, the IFD transmitting/receiving module 620 may transmit/receive a signal through the horizontal polarized transmitting/receiving unit of the tri polarized antenna ANT61, and the IFD transmitting/receiving module 630 may transmit/receive a signal through the azimuth polarized transmitting/receiving unit of the tri polarized antenna ANT61. Further, the IFD transmitting/receiving module 640 may transmit/receive a signal through the vertical polarized transmitting/receiving unit of the tri polarized antenna ANT62, the IFD transmitting/receiving module 650 may transmit/receive a signal through the horizontal polarized transmitting/receiving unit of the tri polarized antenna ANT62, and the IFD transmitting/receiving module 660 may transmit/receive a signal through the azimuth polarized transmitting/receiving unit of the tri polarized antenna ANT62.

Each of the IFD transmitting/receiving modules 610, 620, 630, 640, 650, and 660 may include one of distributors D61, D62, D63, D64, D65, and D66, the analog circuit unit, and the digital circuit unit.

Meanwhile, to avoid the overlapping description, the detailed description of some components (distributors D61, D62, D63, D64, D65, and D66, low noise amplifiers LNA61, LNA62, LNA63, LNA64, LNA65, and LNA66, integrators INT61, INT62, INT63, INT64, INT65, and INT66, digital to analog converters DAC61, DAC62, DAC63, DAC64, DAC65, and DAC66, mixers MIX61, MIX62, MIX63, MIX64, MIX65, and MIX66, power amplifiers PA61, PA62, PA63, PA64, PA65, and PA66, FIR filters FIR61, FIR62, FIR63, FIR64, FIR65, and FIR66, a decoder DEC60, encoders ENC61, ENC62, ENC63, ENC64, ENC65, and ENC66, a digital interference canceller DSIC60, and digital reference generators DRG61, DRG62, DRG63, DRG64, DRG65, and DRG66) performing the same function as the components of the IFD transmitting/receiving modules 110 and 120 according to the first exemplary embodiment of the present invention among the components configuring the respective IFD transmitting/receiving modules 610, 620, 630, 640, 650, and 660 will be omitted below.

FIG. 6 illustrates, for example, the case in which the IFD transmitting/receiving modules 610, 620, 630, 640, 650, and 660 share the digital interference canceller DSIC60 and the decoder DEC60, but the present invention is not limited thereto. Therefore, the digital interference canceller and the decoder may also be separately implemented for each IFD transmitting/receiving modules 610, 620, 630, 640, 650, and 660.

Meanwhile, unlike the IFD transceiver 400 of FIG. 4, when the distance between the tri polarized antennas ANT61 and ANT62 is sufficiently secured, in the IFD transceiver 600 according to the sixth exemplary embodiment of the present invention, the FIR filter for canceling the interference between the antennas ANT61 and ANT62 may be omitted.

Therefore, in the IFD transceiver 600 according to the sixth exemplary embodiment of the present invention, the respective IFD transmitting/receiving modules 610, 620, 630, 640, 650, and 660 require only one FIR filter for canceling the SI occurring due to their own transmitted signals. Therefore, the IFD transceiver 600 according to the sixth exemplary embodiment of the present invention uses only a total of six FIR filters to cancel the SI.

The IFD transceiver 600 according to the sixth exemplary embodiment of the present invention having the foregoing structure may be operated as a 6×6 MIMO transceiver. Both of the two tri polarized antennas ANT61 and ANT62 may simultaneously transmit/receive six polarized signals through six polarized transmitting/receiving units. Therefore, when the IFD transceiver 600 uses the polarized signal to obtain the multiplexing gain or the polarized diversity, 6×6 MIMO may be implemented only by the two tri polarized antennas.

Therefore, when two communication nodes multiplex different data into the vertical polarized signal, the horizontal polarized signal, and the azimuth polarized signal through the IFD transceiver 600 according to the sixth exemplary embodiment of the present invention and exchange the data, it is possible to secure the link capacity up to twelve times as high as the SISO transceiver operated in the HD mode and up to six times as high as the SISO transceiver operated in the IFD mode.

Meanwhile, FIG. 6 illustrates, for example, the case in which the IFD transceiver 600 includes the two tri polarized antennas ANT61 and ANT62, but the present invention is not limited thereto. Therefore, the IFD transceiver 600 may be modified to include more tri polarized antennas. In this case, the IFD transceiver 600 may include 3×N (here, N is the number of tri polarized antennas) IFD transmitting/receiving modules and 3N FIR filters. Further, the IFD transceiver 600 may be operated as 3N×3N MIMO transceivers to secure link capacity up to 9N times as high as the SISO transceiver operated in the HD mode and up to 3N times as high as the SISO transceiver operated in the IFD mode.

Meanwhile, if the transmitting/receiving apparatus may sufficiently secure the distance between the antennas of the base station, the relay station, etc., of the cellular system, even when a MIMO IFD transceiver is implemented using a plurality of non-polarized antennas, the FIR filter for canceling the SI between different antennas may be omitted.

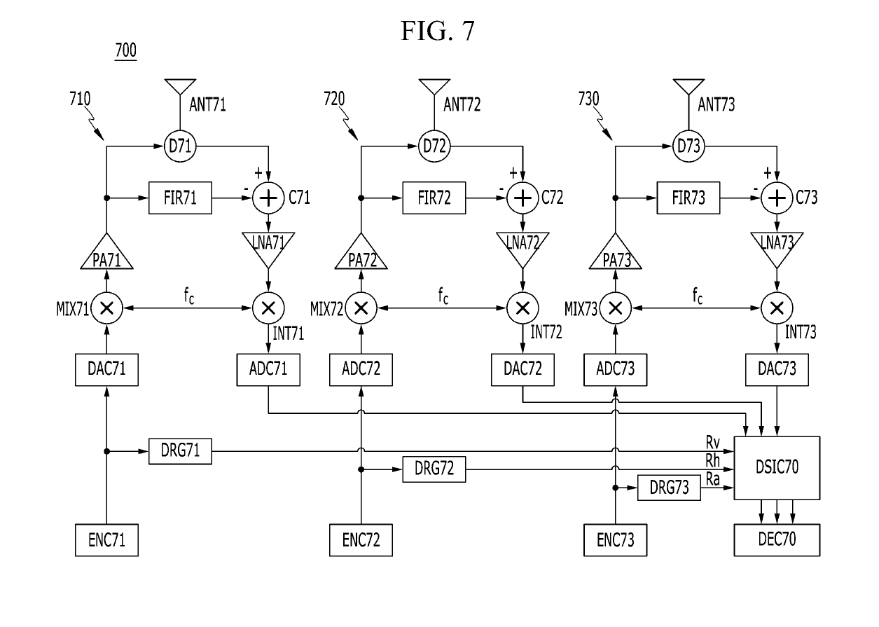

FIG. 7 is a diagram schematically illustrating an IFD transceiver according to a seventh exemplary embodiment of the present invention.

Referring to FIG. 7, an IFD transceiver 700 according to a seventh exemplary embodiment of the present invention may include a plurality of non-polarized antennas ANT71, ANT72, and ANT73 and a plurality of IFD transmitting/receiving modules 710, 720, and 730 connected with the plurality of antennas ANT71, ANT72, and ANT73, respectively.

In FIG. 4, the IFD transceiver 700 includes the three antennas ANT71, ANT72, and ANT73, and therefore includes three IFD transmitting/receiving modules 710, 720, and 730 connected thereto, respectively. That is, the IFD transceiver 700 may include the IFD transmitting/receiving module 710 connected with the antenna ANT71, the IFD transmitting/receiving module 720 connected with the antenna ANT72, and the IFD transmitting/receiving module 730 connected with the antenna ANT73.

The IFD transmitting/receiving modules 710, 720, and 730 transmit/receive signals independent of each other. For example, the IFD transmitting/receiving module 710 may transmit/receive a signal through the antenna ANT71, the IFD transmitting/receiving module 720 may transmit/receive a signal through the antenna ANT72, and the IFD transmitting/receiving module 730 may transmit/receive a signal through the antenna ANT73.

Each of the IFD transmitting/receiving modules 710, 720, and 730 may include one of distributors D71, D72, and D73, the analog circuit unit, and the digital circuit unit.

Meanwhile, to avoid the overlapping description, the detailed description of some components (distributors D51, D52, and D53, low noise amplifiers LNA71, LNA72, and LNA73, integrators INT71, INT72, and INT73, digital to analog converters DAC71, DAC72, and DAC73, mixers MIX71, MIX72, and MIX73, power amplifiers PA71, PA72, and PA73, FIR filters FIR71, FIR72, and FIR73, a decoder DEC70, encoders ENC71, ENC72, and ENC73, a digital interference canceller DSIC70, and digital reference generators DRG71, DRG72, and DRG73) performing the same function as the components of the IFD transmitting/receiving modules 110 and 120 according to the first exemplary embodiment of the present invention among the components configuring the respective IFD transmitting/receiving modules 710, 720, and 730 will be omitted below.

FIG. 7 illustrates, for example, the case in which the IFD transmitting/receiving modules 710, 720, and 730 share the digital interference canceller DSIC70 and the decoder DEC70, but the present invention is not limited thereto. Therefore, the digital interference canceller and the decoder may also be separately implemented for each IFD transmitting/receiving modules 710, 720, and 730.

Meanwhile, when the IFD transceiver 700 according to the seventh exemplary embodiment of the present invention sufficiently secures the distance among the dual polarized antennas ANT71, ANT72, and ANT 73, the FIR filter for canceling the interference between the antennas may be omitted.

Therefore, in the IFD transceiver 700 according to the seventh exemplary embodiment of the present invention, the respective IFD transmitting/receiving modules 710, 720, and 730 include only one FIR filter for canceling the SI occurring due to their own transmitted signals. Therefore, the IFD transceiver 700 according to the seventh exemplary embodiment of the present invention uses only a total of three FIR filters to cancel the SI.

The exemplary embodiments of the present invention are not implemented only by the apparatus and/or method as described above, but may be implemented by programs recorded in a recording medium for realizing the functions corresponding to the configuration of the exemplary embodiments of the present invention or the recording medium recorded with the programs, which may be readily implemented by a person having ordinary skill in the art to which the present invention pertains from the description of the foregoing exemplary embodiments.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An in-band full duplex transceiver, comprising:
a first multi polarized antenna including a plurality of first polarized transmitting/receiving units transmitting/receiving different polarizations; and
a plurality of first transmitting/receiving modules each connected with the plurality of first polarized transmitting/receiving units, receiving first received signals through the plurality of first polarized transmitting/receiving units, and transmitting first transmitted signals through the plurality of first polarized transmitting/receiving units,
wherein each of the first transmitting/receiving modules includes
a first analog circuit unit including a first finite impulse response filter that converts a first analog received signal received through the corresponding first polarized transmitting/receiving unit into a first digital received signal, converts a first digital transmitted signal into a first analog transmitted signal, and uses the first analog transmitted signal to cancel self-interference from the first analog received signal; and
a first distributor transmitting the first analog received signal input from the corresponding first polarized transmitting/receiving unit to the first analog circuit unit and transmitting the first analog transmitted signal input from the first analog circuit unit to the corresponding first polarized transmitting/receiving unit.

2. The in-band full duplex transceiver of claim 1, wherein:
the first finite impulse response filter uses the first analog transmitted signal to generate a first interference cancellation signal, and
the first analog circuit unit further includes a first adder that adds the first interference cancellation signal to the first analog received signal to cancel the self-interference from the first analog received signal.

3. The in-band full duplex transceiver of claim 2, wherein:
the first analog circuit unit further includes:
a low noise amplifier amplifying and outputting the first analog received signal from which the self-interference is canceled by the first adder; and
an analog to digital converter converting the first analog received signal amplified by the low noise amplifier into the first digital received signal.

4. The in-band full duplex transceiver of claim 3, wherein:
the first analog circuit unit further includes:
a digital to analog converter converting the first digital transmitted signal into the first analog transmitted signal; and
a power amplifier amplifying the first analog transmitted signal converted by the digital to analog converter and outputting the amplified first analog transmitted signal to the first distributor and the first finite impulse response filter.

5. The in-band full duplex transceiver of claim 1, wherein:
each of the first transmitting/receiving modules further includes:
a digital circuit unit decoding the first digital received signal to output first received data and encoding first transmitted data to generate the first digital transmitted signal.

6. The in-band full duplex transceiver of claim 5, wherein:
the digital circuit unit further includes:
a digital self-interference canceller using the first digital transmitted signal to cancel the self-interference from the first digital received signal.

7. The in-band full duplex transceiver of claim 6, wherein:
the digital circuit unit further includes:
an encoder encoding the first transmitted data to output the first digital transmitted signal.

8. The in-band full duplex transceiver of claim 7, wherein:
the digital circuit unit further includes:
a digital reference generator distorting the first digital transmitted signal output from the encoder on the basis of a distortion on a receiving path of the first transmitting/receiving module and outputting the distorted first digital transmitted signal to the digital self-interference canceller, and
the digital self-interference canceller uses the first digital transmitted signal distorted by the digital reference generator to cancel the self-interference from the first digital received signal.

9. The in-band full duplex transceiver of claim 6, wherein:
the digital circuit unit further includes:
a decoder decoding the first digital received signal from which the self-interference is canceled by the digital self-interference canceller to output the first received data.

10. The in-band full duplex transceiver of claim 1, further comprising:
a second multi polarized antenna including a plurality of second polarized transmitting/receiving units transmitting/receiving different polarizations; and
a plurality of second transmitting/receiving modules each connected with the plurality of second polarized transmitting/receiving units, receiving second received signals through the plurality of second polarized transmitting/receiving units, and transmitting second transmitted signals through the plurality of second polarized transmitting/receiving units,
wherein each of the second transmitting/receiving modules includes
a second analog circuit unit including a second finite impulse response filter that converts a second analog received signal received through the corresponding second polarized transmitting/receiving unit into a second digital received signal, converts a second digital transmitted signal into a second analog transmitted signal, and uses the second analog transmitted signal to cancel self-interference from the second analog received signal; and
a second distributor transmitting the second analog received signal input from the corresponding second polarized transmitting/receiving unit to the second analog circuit unit and transmitting the second analog transmitted signal input from the second analog circuit unit to the corresponding second polarized transmitting/receiving unit.

11. The in-band full duplex transceiver of claim 10, wherein:
the second finite impulse response filter uses the second analog transmitted signal to generate a second interference cancellation signal, and
the second analog circuit unit further includes a second adder that adds the second interference cancellation signal to the second analog received signal to cancel the self-interference from the second analog received signal.

12. The in-band full duplex transceiver of claim 11, further comprising:
a third finite impulse response filter using a first analog transmitted signal to cancel interference of the corresponding first polarized transmitting/receiving unit from a second analog received signal of a second polarized transmitting/receiving unit transmitting/receiving the same polarization as the corresponding first polarized transmitting/receiving unit among the plurality of second polarized transmitting/receiving units; and
a fourth finite impulse response filter using the second analog transmitted signal to cancel interference of the corresponding second polarized transmitting/receiving unit from a first analog received signal of a first polarized transmitting/receiving unit transmitting/receiving the same polarization as the corresponding second polarized transmitting/receiving unit among a plurality of first polarized transmitting/receiving units.

13. The in-band full duplex transceiver of claim 12, wherein:
the third finite impulse response filter uses the first analog transmitted signal to generate a third interference cancellation signal, and
the second adder adds the third interference cancellation signal to the second analog received signal to cancel the interference of the corresponding first polarized transmitting/receiving unit.

14. The in-band full duplex transceiver of claim 12, wherein:
the fourth finite impulse response filter uses the first analog transmitted signal to generate a fourth interference cancellation signal, and
a first adder adds the fourth interference cancellation signal to the first analog received signal to cancel the interference of the corresponding second polarized transmitting/receiving unit.

15. An in-band full duplex transceiver, comprising:
a plurality of multi polarized antennas including a plurality of polarized transmitting/receiving units transmitting/receiving a plurality of polarizations;
a plurality of transmitting/receiving modules each connected with the plurality of polarized transmitting/receiving units, receiving received signals through the plurality of polarized transmitting/receiving units, and transmitting transmitted signals through the plurality of polarized transmitting/receiving units; and
a plurality of first finite impulse response filters using the transmitted signals to cancel interference between the polarized transmitting/receiving units transmitting/receiving the same polarization as each other from the plurality of multi polarized antennas.

16. The in-band full duplex transceiver of claim 15, wherein:
each of the transmitting/receiving modules includes:
an analog circuit unit including a second finite impulse response filter that converts an analog received signal received through the corresponding polarized transmitting/receiving unit into a digital received signal, converts a digital transmitted signal into an analog transmitted signal, and uses the analog transmitted signal to cancel self-interference from the analog received signal; and
a distributor transmitting the analog received signal input from the corresponding polarized transmitting/receiving unit to the analog circuit unit and transmitting the analog transmitted signal input from the analog circuit unit to the corresponding polarized transmitting/receiving unit.

17. The in-band full duplex transceiver of claim 16, wherein:
the first finite impulse response filter
uses a transmitted signal of a first polarized transmitting/receiving unit among the transmitting/receiving units transmitting/receiving the same polarization as each other to cancel interference of the first polarized transmitting/receiving unit from a received signal of a second polarized transmitting/receiving unit.

18. The in-band full duplex transceiver of claim 15, wherein:
each of the transmitting/receiving modules further includes:
a digital circuit unit decoding a digital received signal to output received data and encoding transmitted data to generate a digital transmitted signal.

19. The in-band full duplex transceiver of claim 18, wherein:
the digital circuit unit further includes:
a digital self-interference canceller using the digital transmitted signal to cancel self-interference from the digital received signal.

20. The in-band full duplex transceiver of claim 19, wherein:
the digital circuit unit further includes:
an encoder encoding the transmitted data to output the digital transmitted signal; and
a digital reference generator distorting the digital transmitted signal output from the encoder on the basis of a distortion on a receiving path of the transmitting/receiving module and outputting the distorted digital transmitted signal to the digital self-interference canceller, and
the digital self-interference canceller uses the digital transmitted signal distorted by the digital reference generator to cancel the self-interference from the digital received signal.
